(19) United States
(12) Patent Application Publication
(10) Pub. No.: US 2025/0125139 A1
(43) Pub. Date: Apr. 17, 2025

(54) APPARATUS FOR REMOVING STATIC ELECTRICITY OF SEMICONDUCTOR SUBSTRATE

(71) Applicant: NEXTIN, INC., Hwaseong-si, Gyeonggi-do (KR)

(72) Inventors: Seoung-Ju NA, Yongin-si, Gyeonggi-do (KR); Heung-Gyoon PARK, Yongin-si, Gyeonggi-do (KR)

(73) Assignee: NEXTIN, INC., Hwaseong-si, Gyeonggi-do (KR)

(21) Appl. No.: 18/682,040

(22) PCT Filed: Jun. 23, 2022
(86) PCT No.: PCT/KR2022/008958

§ 371 Date: Feb. 7, 2024

(30) Foreign Application Priority Data
Aug. 12, 2021 (KR) 10-2021-0106506

(51) Int. Cl. H01J 65/04; H01J 61/02; H01J 61/34

(52) U.S. Cl. CPC H01J 65/04; H01J 61/025; H01J 61/34; H01J 2237/04924

(57) ABSTRACT

An apparatus for removing static electricity of a semiconductor substrate, which removes static electricity embedded inside a thin film on the semiconductor substrate by emitting vacuum ultraviolet (VUV) light to the semiconductor substrate disposed inside a vacuum chamber. The apparatus includes: a VUV generator disposed at an upper side of the vacuum chamber and provided with a VUV lamp configured to emit small-area VUV light into an inside of the vacuum chamber; and a light diffusion unit disposed below the VUV generator and configured to diffuse incident VUV light into a wide area and output the diffused VUV light to the semiconductor substrate disposed below the light diffusion unit.

### CROSS-REFERENCE TO PRIOR APPLICATIONS

This application is a National Stage patent application of PCT International Application No. PCT/KR2022/008958 (filed on Jun. 23, 2022), which claims priority to Korean Patent Application No. 10-2021-0106506 (filed on Aug. 12, 2021), which are all hereby incorporated by reference in their entirety.

### BACKGROUND

The present invention relates to an apparatus for neutralizing static electricity formed in a semiconductor substrate and a pattern located on the semiconductor substrate using vacuum ultraviolet (VUV) light, and more particularly, to a technology capable of expanding a range of VUV light emitted toward a semiconductor substrate and easily removing static electricity embedded in a thin film on a large-area semiconductor substrate.

Recently, as the integration of the semiconductor industry has increased, the size of semiconductor devices has tended to decrease. Thus, a size of a pattern forming a semiconductor device and a thickness of a thin film are decreasing, and in particular, factors that were not significant influences in the related art are emerging as important factors in the development of semiconductor devices. One of these factors is static electricity formed in a semiconductor substrate.

The causes of static electricity formed in a semiconductor substrate include the use of deionized water, charge transfer from charged plastic materials, and induction charging.

The static electricity of the semiconductor substrate mainly occurs in a photo process or a cleaning process using a rotational movement, and it is known that most static electricity is concentrated in a central portion of the semiconductor substrate due to a difference in centrifugal force. That is, due to high-speed rotation of a wafer in a photoresist coating process, a concentration of an airflow in the central portion of the semiconductor substrate increases to three or more times that of an outer periphery, and thus the static electricity is charged around the central portion where a centrifugal force is relatively weak. In particular, the static electricity due to a strong electric field formed in the central portion of the semiconductor substrate is charged in a multi-layered film of the wafer and in a photoresist pattern formed on a surface of the wafer.

FIG. 1A shows an example of a shape in which electrostatic voltages of −50 V, −30 V, and −10 V appear from a central portion to an outer periphery of a semiconductor substrate 1.

However, as shown in FIG. 1A, when the central portion of the semiconductor substrate 1 is charged with a high voltage, since charges are charged on the surface of the substrate 1, which is a photoresist PR or oxide that is an insulator, and charged to a certain depth D from the surface of the semiconductor substrate 1 in an area corresponding to the central portion of the semiconductor substrate 1 (an area where the electrostatic voltage is −50 V in FIG. 1A) in FIG. 1B, a state in which neutralization by ions having low kinetic energy is impossible may occur. In addition, the electrostatic voltage charged into the semiconductor substrate varies due to many variables such as the type of process, material, and pattern shape and is generally formed between −200 V and +200 V.

In this regard, a configuration for removing static electricity from a semiconductor substrate using an ionizer is disclosed in Patent Document 1 (Korean Patent Registration No. 10-1698273) and Patent Document 2 (Korean Patent Laid-Open Application No. 10-2004-0040106).

For example, as shown in FIG. 1B, when a charging voltage of 100 V or less is formed on the semiconductor substrate 1 which includes an insulating film within a microcircuit of 10 nm or in which a pattern P having an aspect ratio of “5” or more is formed, since a pattern width is narrow, it is difficult to remove static electricity accumulated in the thin film due to a self-neutralization effect between positive ions and negative ions generated from an ionizer and a decrease in collisions of ions due to a low electromotive force according to a low voltage difference between the semiconductor substrate and the ions.

In addition, a decay time of one to two seconds is required for reducing static electricity charged in the semiconductor substrate at a voltage of 1000 V to a charging voltage within 100 V using a soft X-ray ionizer. However, when an initial charging voltage of 100 V or less is formed, it takes a long time to reduce the charging voltage to a target voltage or less.

In addition, the ionizer generates vacuum ultraviolet (VUV) light to remove static electricity from the substrate. Since a divergence angle of the VUV light emitted from an ionizer lamp is very small, approximately ±7°, in order to remove static electricity from a large-area semiconductor substrate, a very long separation distance is required between the ionizer and the large-area semiconductor substrate. That is, there are problems in that not only should the size of a vacuum chamber performing the static electricity removal process of the semiconductor substrate be designed to be larger in proportion to the area of the semiconductor substrate, but also, since energy of the VUV light decreases significantly according to an emission distance, a long static electricity removal time is required for removing the static electricity charged in the semiconductor substrate at a certain level or higher.

In addition, considering that an ion density of the ionizer is generally 10⁶, when an ion density becomes 10⁸ or more inside a silicon oxide layer in the semiconductor substrate below the photoresist PR, the static electricity formed inside the semiconductor substrate 1 cannot be removed using the existing ionizer.

In this case, there may be a way to remove static electricity from the semiconductor substrate by generating a high-density plasma of 10⁹ or more in the vacuum chamber.

However, when the vacuum chamber is formed, a problem may occur in which an ion beam is additionally charged inside a front surface due to self-bias and plasma uniformity according to the type of plasma. In addition, fine circuits may be formed in irregular patterns on the semiconductor substrate, and static electricity of different voltages may be charged inside each portion according to characteristics of the pattern. That is, static electricity voltages of −100 V to +100 V may be distributed according to portions of the semiconductor substrate.

Therefore, when ions are uniformly provided throughout the substrate, ions with the same intensity are emitted to the entire surface of the semiconductor substrate, and thus charging due to overshooting may additionally occur in areas where a voltage level higher than the static electricity voltage generated on the semiconductor substrate is applied.

Furthermore, when charges are charged inside an oxide film and/or pattern, ions should be provided with high energy in order to neutralize the static electricity, but when reactive radicals and/or reactive ions are emitted to the substrate with high energy, they may collide with the substrate and the pattern formed on the surface of the substrate and cause damage.

In particular, in the case of a semiconductor substrate with an extremely fine pattern of 10 nm or less, charging by positive ions, negative ions, or electrons has a greater impact on the performance and yield of the semiconductor device.

### SUMMARY

The present invention is directed to providing an apparatus for removing static electricity of a semiconductor substrate, which can easily neutralize static electricity formed on a large-area semiconductor substrate without expanding an area of a vacuum chamber by expanding vacuum ultraviolet (VUV) light with a small area generated from a generator through a diffractive optical element to emit the VUV light to the semiconductor substrate.

The present invention is also directed to providing an apparatus for removing static electricity of a semiconductor substrate, which can accurately and quickly remove static electricity embedded (charged) inside a thin film on a semiconductor substrate within a short period of time by supplying different voltages to a plurality of electrode regions with different areas, which are separated from each other, and emitting VUV light corresponding to the static electricity voltage formed on the semiconductor substrate to the semiconductor substrate through a hole formed in the electrode region.

One aspect of the present invention provides an apparatus for removing static electricity of a semiconductor substrate, which removes static electricity embedded inside a thin film on the semiconductor substrate by emitting vacuum ultraviolet (VUV) light to the semiconductor substrate disposed inside a vacuum chamber, including a VUV generator disposed at an upper side of the vacuum chamber and provided with a VUV lamp configured to emit small-area VUV light into an inside of the vacuum chamber, and a light diffusion unit disposed below the VUV generator and configured to diffuse incident VUV light into a wide-area and output the diffused VUV light to the semiconductor substrate disposed below the light diffusion unit.

Another aspect of the present invention provides an apparatus for removing static electricity of a semiconductor substrate, which removes static electricity formed on the semiconductor substrate by emitting vacuum ultraviolet (VUV) light to the semiconductor substrate disposed inside a vacuum chamber, including a plasma generator disposed at an upper side of the vacuum chamber and configured to form plasma through reaction of a process gas and emit VUV light into an inside of the vacuum chamber, and a light diffusion unit disposed below the plasma generator and configured to diffuse incident VUV light into a wide area and output the diffused VUV light to the semiconductor substrate disposed below the light diffusion unit.

The light diffusion unit may be a beam splitter.

The light diffusion unit may be formed of a metal mesh or a metal plate in which a plurality of holes are formed.

The light diffusion unit may be formed in a multi-lens array structure in which a number of micro lenses are disposed on a substrate made of one of MgF₂, CaF₂, LiF, and sapphire.

A grid plate, which has a structure in which a central electrode region with a predetermined size is disposed in a central portion, and one or more peripheral electrode regions having one or more band shapes are disposed around the central electrode region so that the electrode regions are separated from each other, may be additionally disposed below the light diffusion unit, the electrode region may be made of a metal material in which a plurality of holes are formed, and different voltages may be supplied to the electrode regions.

A separation plate may be additionally provided inside the vacuum chamber to separate an upper space from a lower space based on the light diffusion unit, and the light diffusion unit may be formed on the separation plate.

The upper space and the lower space of the vacuum chamber may each be provided with a vacuum setting unit configured to set a vacuum state of a corresponding space, and a vacuum level of the upper space may be set high than a vacuum level of the lower space.

The substrate support may be made of a metal material, a positive (+) or negative (−) bias voltage may be supplied to the substrate support, the positive (+) bias voltage may be supplied to lead electrons to the semiconductor substrate, and the negative (−) bias voltage may be supplied to lead ions to the semiconductor substrate.

A plurality of VUV generators may be disposed on an upper side of the vacuum chamber at regular intervals to emit VUV light, and the light diffusion unit may expand and output a plurality of VUV light beams emitted from the VUV generators to an entire surface of the semiconductor substrate.

A plurality of plasma generators are disposed on an upper side of the vacuum chamber at regular intervals to emit VUV light, the light diffusion unit may expand and output a plurality of VUV light beams emitted from the VUV generators to an entire surface of the semiconductor substrate, and the plasma generators may be formed to react with different process gases and emit the plurality of VUV light beams in different bands.

A rotation part may be provided below a substrate support configured to support the semiconductor substrate to rotate the substrate support while the VUV light is emitted from the VUV generator, and the light diffusion unit may be formed as at least one optical diffusion module positioned eccentrically from a center of the semiconductor substrate.

In accordance with the present invention, static electricity formed on a large-area semiconductor substrate can be easily neutralized without expanding an area of a vacuum chamber by expanding an output range of vacuum ultraviolet (VUV) light emitted toward the semiconductor substrate inside the vacuum chamber.

In addition, by adjusting power applied to a grid plate to correspond to static electricity charged in the semiconductor substrate and adjusting a quantity of VUV light emitted to the semiconductor substrate, the static electricity differently charged in the semiconductor substrate can be accurately removed to minimize a defective rate due to a semiconductor manufacturing process and manufacture a more reliable semiconductor device.

### BRIEF DESCRIPTION OF THE DRAWINGS

FIG. 1 is a diagram for describing the problem of static electricity removal in a semiconductor substrate.

FIG. 2 is a schematic diagram illustrating an apparatus for removing static electricity of a semiconductor substrate according to a first embodiment of the present invention.

FIG. 3 is a diagram illustrating a structure of a light diffusion unit (200) shown in FIG. 2.

FIG. 4 is a diagram for describing an apparatus for removing static electricity of a semiconductor substrate according to a second embodiment of the present invention.

FIG. 5 is a diagram for describing an apparatus for removing static electricity of a semiconductor substrate according to a third embodiment of the present invention.

FIG. 6 is a diagram illustrating a structure of a grid plate (400) shown in FIG. 5.

FIG. 7 is a diagram for describing an apparatus for removing static electricity of a semiconductor substrate according to a fourth embodiment of the present invention.

FIG. 8 is a diagram illustrating a structure of a light diffusion unit (200) shown in FIG. 7.

FIG. 9 is a diagram for describing an apparatus for removing static electricity of a semiconductor substrate according to a fifth embodiment of the present invention.

### DETAILED DESCRIPTION

Embodiments described in the present invention and configurations shown in the accompanying drawings are merely exemplary embodiments of the present invention and do not represent all the technical ideas of the present invention so that the scope of the present invention should not be construed as being limited by the embodiments and drawings described herein. That is, since the embodiments can be variously alternated and have various forms, it should be understood that the scope of the present invention includes equivalents capable of implementing the technical ideas. In addition, the objectives or effects proposed in the present invention do not mean that a specific embodiment should include all the objectives or effects or only such effects, and therefore the scope of the present invention should not be construed as being limited thereto.

Unless otherwise defined all terms used herein have the same meanings as commonly understood by those skilled in the art to which the invention pertains. General terms that are defined in a dictionary shall be construed to have meanings that are consistent in the context of the relevant art and should not be interpreted as having an idealistic or excessively formalistic meaning unless clearly defined in the present invention.

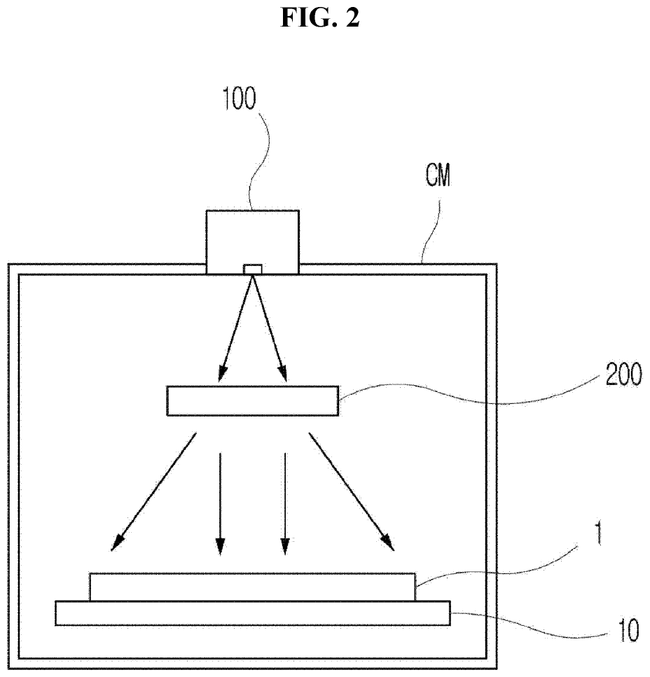

FIG. 2 is a schematic diagram illustrating an apparatus for removing static electricity of a semiconductor substrate according to a first embodiment of the present invention.

Referring to FIG. 2, in the apparatus for removing static electricity of a semiconductor substrate according to the present invention, a vacuum ultraviolet (VUV) generator 100 is disposed in an upper side of a vacuum chamber CM in which a semiconductor substrate 1 is placed, a light diffusion unit 200 is disposed inside the vacuum chamber CM to expand and output an emission range of VUV light emitted from the VUV generator 100, and the semiconductor substrate 1 is placed on an upper surface of a substrate support 10 below the light diffusion unit 200. In addition, devices disposed inside the vacuum chamber CM are controlled through a controller (not shown).

The VUV generator 100 may be formed of a VUV ionizer. The VUV ionizer generates VUV light with a wavelength band of 110 nm to 400 nm inside the vacuum chamber CM, and the VUV light reacts with a process gas inside the vacuum chamber CM, decomposes gas particles, generates positive ions and electrons, and is emitted toward the semiconductor substrate 1. In this case, the VUV ionizer emits the VUV light with light energy that is greater than a band-gap of a thin film to the thin film where static electricity is accumulated in a lower side of the substrate to form electron and hole pairs within the thin film, thereby neutralizing the static electricity accumulated (embedded) on the semiconductor substrate 1.

In this case, the VUV ionizer emits the VUV light into an inside of the vacuum chamber CM through a deuterium lamp, and a light emission area of the VUV light emitted through the deuterium lamp is approximately 10 mm×10 mm and a divergence angle thereof is ±7°.

The light diffusion unit 200 expands and outputs the divergence angle of the VUV light emitted from the VUV generator 100 and may be formed of a diffractive optical element (DOE).

The DOE is an optical element for spreading an optical path using a diffraction phenomenon due to a structure of the inside of a lens or a surface of the lens, is manufactured using a Fresnel lens, binary optics, a Fresnel zone plate, a hybrid lens, or the like, and includes a beam shaping element, a diffractive laser induced texturing (DLITe) beam splitter, a transmission grating random dot generation element, and the like. In particular, a diffractive spot beam splitter may be used as the DOE and may be made of MgF₂, CaF₂, LiF, or sapphire.

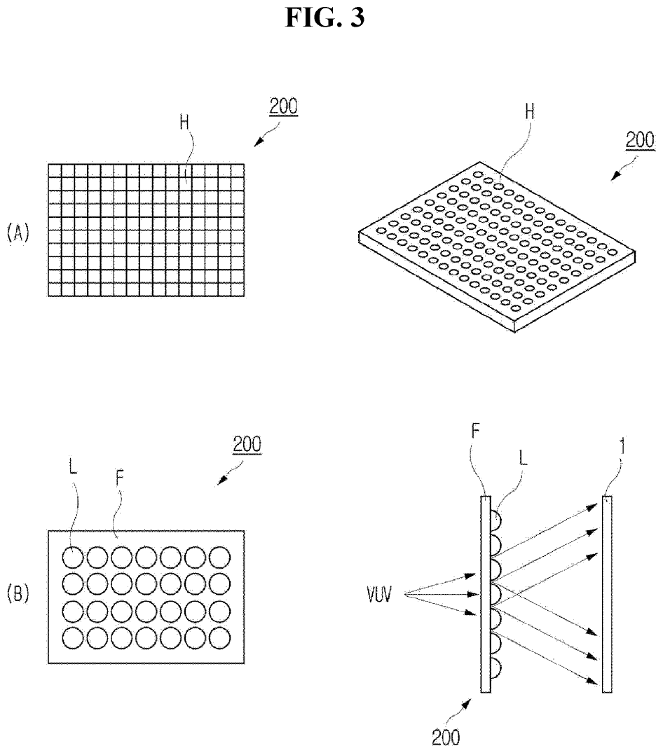

In addition, the light diffusion unit 200 may be made of a metal board having a plurality of holes. For example, as shown in FIG. 3A, the metal board may be made of a mesh of a metal material, that is, a metal mesh, or may be made of a metal plate with a certain thickness and a plurality of holes H formed therein.

The metal board reflects the VUV light emitted from the VUV generator 100 by the metal material, diffuses the VUV light to the surroundings through the holes, and emits the VUV light downward. For example, in the case of UV-polished aluminum (Al), optical reflectivity of the metal board ranges from 70% to 80% in a 120 nm wavelength band.

Alternatively, the light diffusion unit 200 may be formed in a multi-lens array structure in which a plurality of lenses are disposed.

As shown in FIG. 3B, the multi-lens array has a form in which a plurality of micro lenses L are disposed on a substrate I and a micro lens array is formed by forming a pattern with a photoresist on the surface I made of one of MgF₂, CaF₂, LiF, and sapphire and using plasma such as inductively coupled plasma (ICP). In this case, as a result of an experiment performed by arranging a 2 μm micro lens array, which has a size of 20 mm×20 mm with an optical width expanded by 5 times or more, in a central portion of the substrate I and arranging the 2 μm micro lens array to have a distance of within 100 mm from the semiconductor substrate 1, by considering a pump out time during a 300 mm wafer process, it was confirmed that efficiency was increased by 30% or more without rotating the semiconductor substrate 1. Considering the size of the semiconductor substrate 1, static electricity may be removed with only one VUV lamp compared to the existing structure in which three or more VUV lamps should be disposed so that a locally occurring overdose due to VUV light when a plurality of VUV lamps are used can be prevented.

The light diffusion unit 200 with the above structure expands the VUV light with a size of 10 mm×10 mm in a small area range, which is emitted from the VUV generator 100, into the VUV light with a size in a wide area range, for example, 300 mm×300 mm, and emits the VUV light downward.

In addition, the VUV light emitted to the semiconductor substrate 1 through the light diffusion unit 200 infiltrates into a SiO₂ layer of the semiconductor substrate 10 and generates holes and electrons in the oxide, thereby removing charges, that is, static electricity, charged inside the film.

In this case, since the VUV light emitted from the VUV generator 100 undergoes severe energy attenuation according to an internal vacuum degree of the vacuum chamber CM, a vacuum degree of the vacuum chamber CM in which the VUV light is emitted may be set to 10⁻⁴ Torr to minimize energy attenuation of the VUV light.

In addition, the energy attenuation of the VUV light emitted from the VUV generator 100 may be minimized by minimizing the distance between the VUV generator 100 and the light diffusion unit 200.

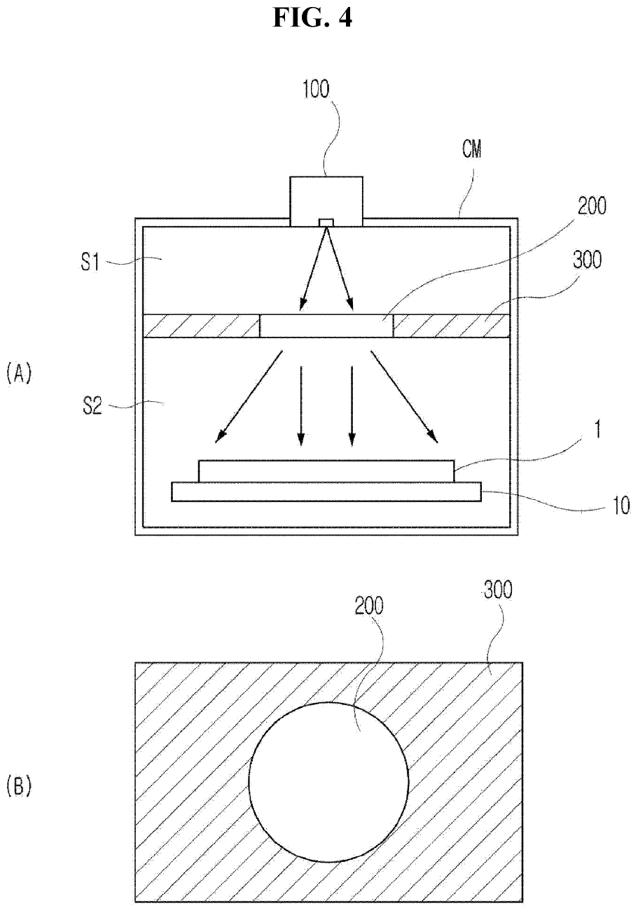

In addition, as shown in FIG. 4, the light diffusion unit 200 may be disposed in a central portion of a separation plate 300 which separates the internal space of the vacuum chamber CM.

The separation plate 300 serves not only to support the light diffusion unit 200 to be positioned inside the vacuum chamber CM, but also to be in contact with an inner surface of the vacuum chamber CM to vacuum seal the inner contact portion, thereby separating the inside of the vacuum chamber CM into an upper space S1 and a lower space S2 based on the light diffusion unit 200.

In this case, vacuum forming units 21 and 22 for controlling a vacuum state by injecting a gas into corresponding spaces may be provided in the upper space S1 and the lower space S2 of the vacuum chamber CM, respectively. The vacuum forming units 21 and 22 may each include a gas inlet for injecting a gas into a corresponding space and a gas outlet for discharging a gas of the vacuum chamber to the outside and may set a vacuum degree of the upper space S1 differently from a vacuum degree of the lower space S2.

For example, in the present invention, the vacuum degree of the upper space S1 in the vacuum chamber CM may be set to 10⁻⁴ Torr in consideration of the energy attenuation characteristics of the VUV light emitted from the VUV generator 100, and the vacuum degree of the lower space S2 in the vacuum chamber CM may be set to 10⁻² Torr.

In addition, different process gases may be injected into the upper space S1 and the lower space S2 in the vacuum chamber CM.

In addition, the substrate support 10 provided inside the vacuum chamber CM is made of a metal material, and a bias voltage of a predetermined level may be supplied to the substrate support 10. This is to ensure that the electrons or ions generated by the VUV light incident on the semiconductor substrate 1 have directivity and reach a lower layer of semiconductor substrate 1. A positive (+) bias voltage is supplied in order to lead the electrons to the semiconductor substrate 1, and a negative (−) bias voltage is supplied in order to lead the ions to the semiconductor substrate 1. In this case, the bias voltage is set in the range of 1 V to ±200 V.

Meanwhile, according to the present invention, a structure with an optical path in which the VUV light is emitted vertically toward the semiconductor substrate 1 in consideration of the fact that patterns having an aspect ratio with a higher level are formed on the upper surface of the semiconductor substrate 1, which is a target from which static electricity is removed, may be formed.

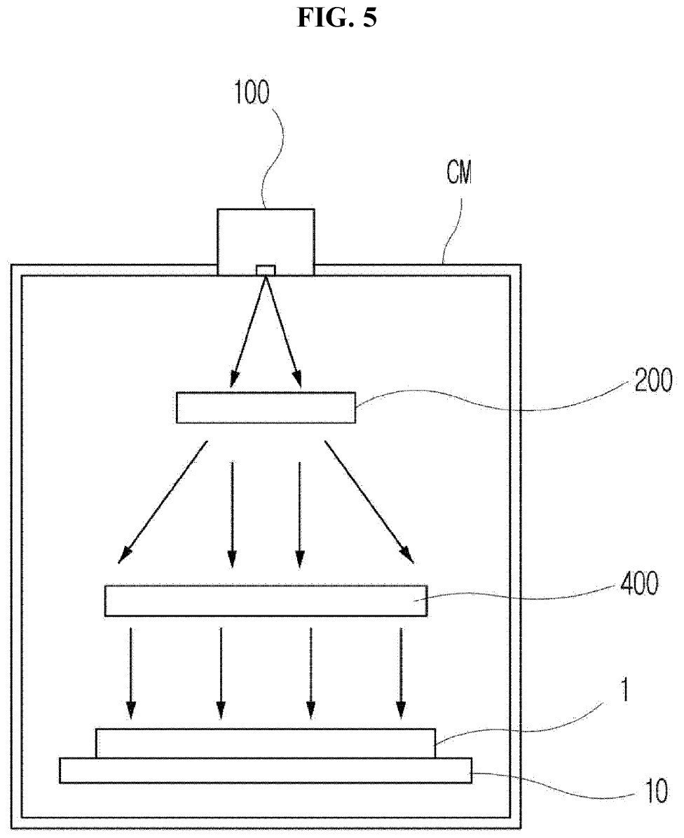

To this end, according to the present invention, as shown in FIG. 5, a grid plate 400 in which a plurality of holes are formed may be additionally disposed below the light diffusion unit 200. In this case, the grid plate 400 is disposed at a position with a separation distance of 100 mm or less from the semiconductor substrate 1, a size of the grid plate 400 is set to be greater than or equal to that of the semiconductor substrate 1, and the grid plate 400 is formed to have a shape similar to that of the semiconductor substrate 1, for example, a circular or quadrangular shape.

The grid plate 400 is made of a metal plate with a thickness of 1 mm to 10 mm and is provided with a plurality of holes, each having a diameter of 0.1 mm to 5 mm. The overall aperture ratio of the holes may be set to be 60% or more of a grid plate area, and the grid plate 400 may be formed as a metal mesh or a metal plate with holes (see FIG. 3A).

That is, the grid plate 400 reflects VUV light at an upper side on a hole wall and changes an optical path of the VUV light, thereby emitting the VUV light toward the semiconductor substrate 1 to enter the semiconductor substrate 1 so that infiltrating efficiency of the VUV light into the thin film in which static electricity of the semiconductor substrate 1 is formed increases.

The grid plate 400 has a structure in which a central electrode region with a predetermined size is disposed in a central portion, and one or more peripheral electrode regions having one or more band shapes are disposed around the central electrode region so that the electrode regions are separated from each other.

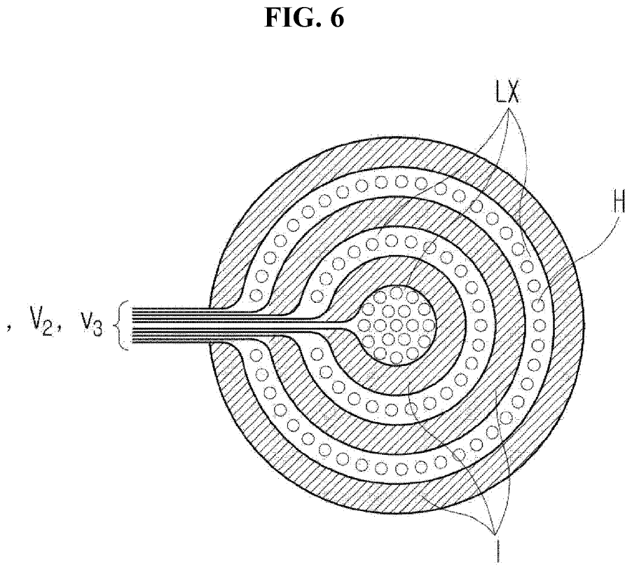

For example, as shown in FIG. 6, the grid plate 400 may be formed such that a plurality of circular electrode regions LX, each having with a predetermined area, in the form of ovals or concentric circles with different diameters are arranged in the form of a growth ring spaced a predetermined distance outward from the same center point.

In this case, the electrode regions LX are placed on insulating plates I and are electrically insulated from each other by the insulating plates I, and holes H formed in each electrode region are formed to pass through the insulating plate I. Here, a wall surface of the hole H of the insulating plate I may be coated with a metal material such as aluminum (Al) or copper (Cu).

This is because the electrode region is formed according to pattern characteristics in which the static electricity voltage formed on the semiconductor substrate 1 due to the characteristics of the semiconductor process is highest in the central portion of the semiconductor substrate 1 and becomes lower toward an outer side.

In this case, the central electrode region of the grid plate 400 may be formed in the form of a disk with a predetermined area to form more holes H than the band-shaped electrode regions on the outer side, and a diameter of the holes may be set to a size of 0.1 mm to 5 mm.

In addition, according to the present invention, different voltages may be supplied to the electrode regions LX of the grid plate 400. In this case, a quantity of light is adjusted to neutralize static electricity voltages of different levels formed in different areas formed in the semiconductor substrate 1 in response to the static electricity voltage formed on the semiconductor substrate 1. For example, a voltage V1 of the central electrode region LX may be set to be the largest, and a voltage of the electrode region LX may be set to gradually decrease toward the outer side (V2>V3>V4).

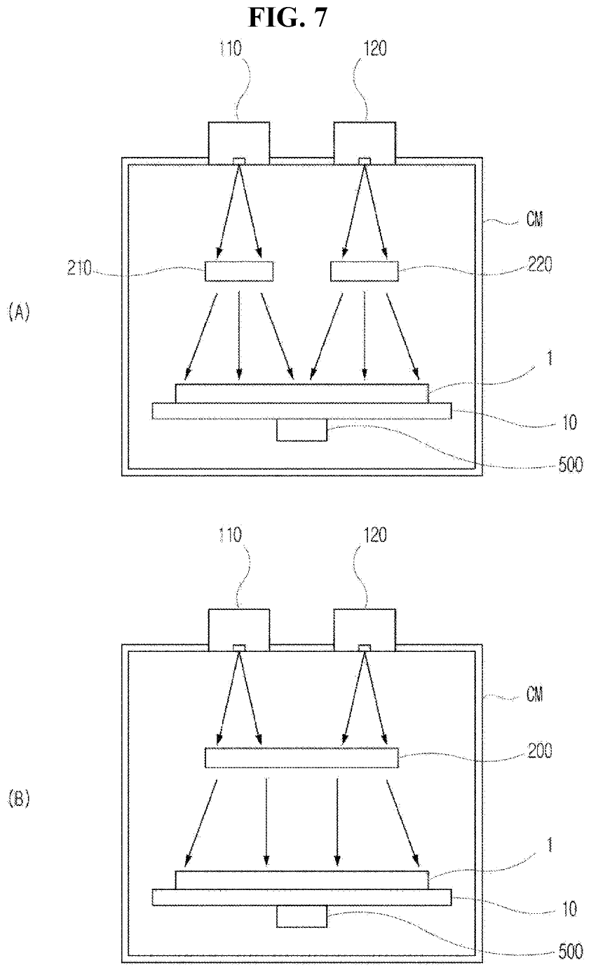

Meanwhile, in the above example, although the semiconductor processing system provided with one VUV ionizer 700 in the central portion of the vacuum chamber CM has been described, as shown in FIG. 7, the above example may be applied to and implemented in a semiconductor processing system provided with two or more VUV ionizers 110 and 120 outputting VUV light at different positions of the upper side of the vacuum chamber CM. FIG. 6 illustrates a shape in which first and second VUV generators 110 and 120 are disposed.

In this case, as shown in FIG. 7A, first and second light diffusion units 210 and 220 may be disposed as the light diffusion unit at positions corresponding to the first and second VUV generators 110 and 120 in a one-to-one correspondence relationship.

Alternatively, as shown in FIG. 7B, the light diffusion unit may be formed as one light diffusion unit 200 with a size corresponding to the overall size of the first and second VUV generators 110 and 120.

In this case, a rotation part 500 for rotating the substrate support 10 may be additionally provided on a bottom surface of the substrate support 10, and the rotation part 500 may rotate the substrate support 10 while VUV light is generated according to the static electricity removal process so that the semiconductor substrate 1 may be rotated at a constant speed.

As described above, in the structure provided with the rotation part 500, the center of the light diffusion unit 200 may be positioned eccentrically from the center C of the semiconductor substrate 1 as shown in FIG. 7A, and the diameter of the light diffusion unit 200 may be greater than or equal to a radius of the semiconductor substrate 1. Therefore, although the diameter of the light diffusion unit 200 is smaller than the diameter of the semiconductor substrate 10, the VUV light is provided to the entire surface of semiconductor substrate 1 as the semiconductor substrate 1 is rotated.

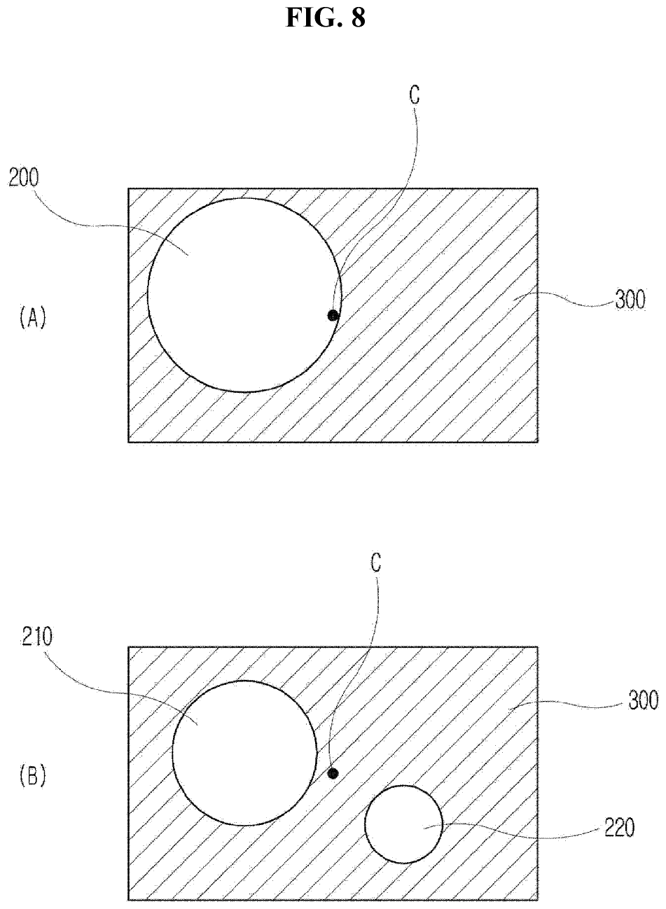

In addition, even in the structure in which the light diffusion unit 200 includes the plurality of light diffusion units 210 and 220, each of the light diffusion units 210 and 220 may have a diameter smaller than the radius of the semiconductor substrate 1, and as shown in FIG. 8B, each of the light diffusion units 210 and 220 may be positioned eccentrically from the center C of the semiconductor substrate 1. In this case, the plurality of light diffusion units 210 and 220 may be disposed such that, when the semiconductor substrate 1 is rotated, there is no portion where the VUV light is not provided to the semiconductor substrate 1, and may be disposed such that an amount of the VUV light is emitted larger than an correspond amount of the static electricity trapped in the center of the semiconductor substrate 1.

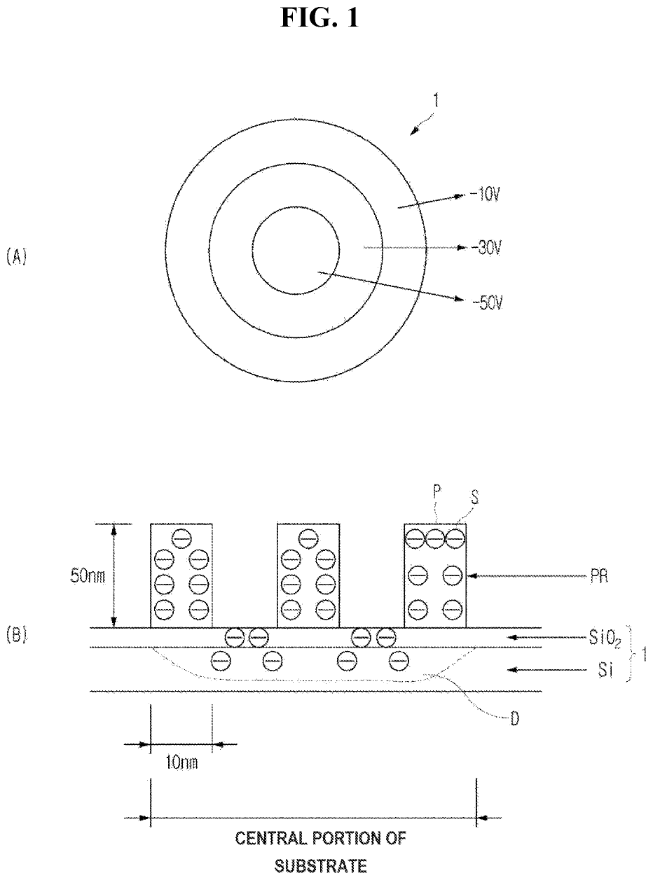

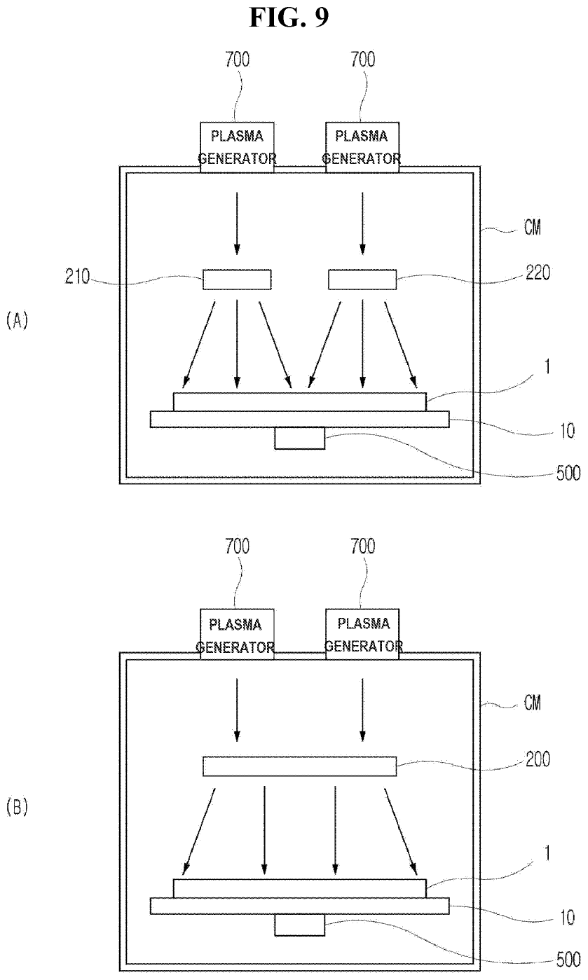

Meanwhile, in the present invention, the static electricity trapped in the semiconductor substrate 1 is removed using the VUV light emitted through the VUV ionizer 100, but in the structures shown in FIGS. 1, 4, 5, and 7, by generating VUV light using a plasma generator instead of the VUV generator, the static electricity embedded within the thin film of the semiconductor substrate 1 may be removed. FIG. 9 illustrates a structure provided with a plurality of plasma generators 700.

As an example, the plasma generator 700 is a capacitively coupled plasma (CCP) forming device, and plasma is formed such that a radio frequency (RF), direct current, or high or low frequency electrical signal is provided to two separated metal electrodes positioned within the device. As an example, the electrical signal provided to the plasma forming unit 110 may be a pulse or continuous wave (CW). As an example, the electrical signal provided to the plasma forming unit 110 may be a pulse or CW.

As another example, the plasma generator 700 is an ICP forming device, a magnetic field is generated as a current flows in a coil positioned within the device, and the ICP forming device is a device which forms plasma from the formed magnetic field. As an example, the electrical signal provided to the plasma forming unit 110 may be a pulse or CW signal in a band of 1 MHz or more.

As another example, the plasma generator 700 may be a microwave providing device and may generate plasma by providing an electrical signal in an RF band to a UV light forming vacuum chamber. As an example, a frequency of the electrical signal provided to the plasma generator is 2.45 GHz or more, and a pulse or CW may be provided. As in the examples, the plasma forming unit 110 forms plasma and may form pulse-time-modulated plasma.

Electrons excited in the plasma formed by the plasma generator 700 transition to a bottom state and emit light, which has energy corresponding to an energy difference between an excited state and the bottom state, to the outside. A wavelength band of light formed in this way may be an infrared band, a visible band, or a UV band. In the present embodiment, in order to neutralize charges trapped in the semiconductor substrate and/or the pattern formed on the semiconductor substrate, the wavelength band of light in a VUV band is formed.

In addition, in the plasma generator 700, the VUV wavelength band emitted to the outside may be set differently according to a type of a process gas used in a plasma source, and the static electricity formed on the semiconductor substrate 1 may vary according to the region. Thus, in the present invention, the VUV wavelength band emitted from the plasma generator 700 may be set differently according to different static electricity levels formed at different positions of the semiconductor substrate 1.

For example, a first plasma generator, which is located at a position corresponding to a region where a static electricity level formed on the semiconductor substrate 1 is low, may form plasma using argon (Ar) and emit VUV light in a 104.4 nm wavelength band, and a second plasma generator, which is located at a position corresponding to a region where a static electricity level is high, may form plasma using oxygen (O₂) and emit VUV light in a 130.5 nm wavelength band.

This can prevent the VUV light from infiltrating into the insulating film due to high-band VUV light and changing the film characteristics in the region where the static electricity level is low on the semiconductor substrate 1.

1. An apparatus for removing static electricity of a semiconductor substrate, which removes static electricity embedded inside a thin film on the semiconductor substrate by emitting vacuum ultraviolet (VUV) light to the semiconductor substrate disposed inside a vacuum chamber, the apparatus comprising:
a VUV generator disposed at an upper side of the vacuum chamber and provided with a VUV lamp configured to emit small-area VUV light into an inside of the vacuum chamber; and
a light diffusion unit disposed below the VUV generator and configured to diffuse incident VUV light into a wide area and output the diffused VUV light to the semiconductor substrate disposed below the light diffusion unit.

2. An apparatus for removing static electricity of a semiconductor substrate, which removes static electricity formed on the semiconductor substrate by emitting vacuum ultraviolet (VUV) light to the semiconductor substrate disposed inside a vacuum chamber, the apparatus comprising:
a plasma generator disposed at an upper side of the vacuum chamber and configured to form plasma through reaction of a process gas and emit VUV light into an inside of the vacuum chamber; and
a light diffusion unit disposed below the plasma generator and configured to diffuse incident VUV light into a wide area and output the diffused VUV light to the semiconductor substrate disposed below the light diffusion unit.

3. The apparatus of claim 1, wherein the light diffusion unit includes a beam splitter.

4. The apparatus of claim 1, wherein the light diffusion unit is formed of a metal mesh or a metal plate in which a plurality of holes are formed.

5. The apparatus of claim 1, wherein the light diffusion unit is formed in a multi-lens array structure in which a number of micro lenses are disposed on a substrate made of one of MgF₂, CaF₂, LiF, and sapphire.

6. The apparatus of claim 1, wherein:
a grid plate, which has a structure in which a central electrode region with a predetermined size is disposed in a central portion, and one or more peripheral electrode regions having one or more band shapes are disposed around the central electrode region so that the electrode regions are separated from each other, is additionally disposed below the light diffusion unit; and
the electrode region is made of a metal material in which a plurality of holes are formed, and different voltages are supplied to the electrode regions.

7. The apparatus of claim 1, wherein:
a separation plate is additionally provided inside the vacuum chamber to separate an upper space from a lower space based on the light diffusion unit; and
the light diffusion unit is formed on the separation plate.

8. The apparatus of claim 7, wherein:
the upper space and the lower space of the vacuum chamber are each provided with a vacuum setting unit configured to set a vacuum state of a corresponding space; and
a vacuum level of the upper space is set differently from a vacuum level of the lower space.

9. The apparatus of claim 1, wherein:
a substrate support is made of a metal material, and a positive (+) or negative (−) bias voltage is supplied to the substrate support; and
the positive (+) bias voltage is supplied to lead electrons to the semiconductor substrate, and the negative (−) bias voltage is supplied to lead ions to the semiconductor substrate.

10. The apparatus of claim 1, wherein:
a plurality of VUV generators are disposed on an upper side of the vacuum chamber at regular intervals to emit VUV light; and
the light diffusion unit expands and outputs a plurality of VUV light beams emitted from the VUV generators to an entire surface of the semiconductor substrate.

11. The apparatus of claim 2, wherein:
a plurality of plasma generators are disposed on an upper side of the vacuum chamber at regular intervals to emit VUV light;
the light diffusion unit expands and outputs a plurality of VUV light beams emitted from the VUV generators to an entire surface of the semiconductor substrate; and
the plasma generators are formed to react with different process gases and emit the plurality of VUV light beams in different bands.

12. The apparatus of claim 10, wherein:
a rotation part is provided below a substrate support configured to support the semiconductor substrate to rotate the substrate support while the VUV light is emitted from the VUV generator; and the light diffusion unit is formed as at least one optical diffusion module positioned eccentrically from a center of the semiconductor substrate.

13. The apparatus of claim 2, wherein the light diffusion unit includes a beam splitter.

14. The apparatus of claim 2, wherein the light diffusion unit is formed of a metal mesh or a metal plate in which a plurality of holes are formed.

15. The apparatus of claim 2, wherein the light diffusion unit is formed in a multi-lens array structure in which a number of micro lenses are disposed on a substrate made of one of MgF₂, CaF₂, LiF, and sapphire.

16. The apparatus of claim 2, wherein:
a grid plate, which has a structure in which a central electrode region with a predetermined size is disposed in a central portion, and one or more peripheral electrode regions having one or more band shapes are disposed around the central electrode region so that the electrode regions are separated from each other, is additionally disposed below the light diffusion unit; and
the electrode region is made of a metal material in which a plurality of holes are formed, and different voltages are supplied to the electrode regions.

17. The apparatus of claim 2, wherein:
a separation plate is additionally provided inside the vacuum chamber to separate an upper space from a lower space based on the light diffusion unit; and
the light diffusion unit is formed on the separation plate.

18. The apparatus of claim 2, wherein:
a substrate support is made of a metal material, and a positive (+) or negative (−) bias voltage is supplied to the substrate support; and
the positive (+) bias voltage is supplied to lead electrons to the semiconductor substrate, and the negative (−) bias voltage is supplied to lead ions to the semiconductor substrate.

19. The apparatus of claim 11, wherein:
a rotation part is provided below a substrate support configured to support the semiconductor substrate to rotate the substrate support while the VUV light is emitted from the VUV generator; and the light diffusion unit is formed as at least one optical diffusion module positioned eccentrically from a center of the semiconductor substrate.
